(19) United States
(12) Patent Application Publication
(10) Pub. No.: US 2008/0001273 A1
(43) Pub. Date: Jan. 3, 2008

(54) Semiconductor package having optimal interval between bond fingers for reduced substrate size

(76) Inventor: Jeong Hyun Park, Seoul (KR)

Correspondence Address: LADAS & PARRY LLP, 224 SOUTH MICHIGAN AVENUE, SUITE 1600, CHICAGO, IL, 60604, US

(21) Appl. No.: 11/647,927

(22) Filed: Dec. 29, 2006

(30) Foreign Application Priority Data
Jun. 29, 2006 (KR) 10-2006-0059812

(51) Int. Cl. H01L 23/02

(52) U.S. Cl. 257/678

(57) ABSTRACT

A semiconductor package includes a semiconductor chip having a plurality of bonding pads, and a substrate having a first surface on which a plurality of bond fingers are arranged and a second surface on which ball lands connected to the bond fingers are formed. The bond fingers are arranged in a plurality of rows, and are formed in the shape of a polygon, such that overlapping surfaces of a bond finger of a row, which overlap with another bond finger of another row, have a constant slope, and overlapping surfaces of bond fingers arranged in the same row, which face each other, are sloped in opposite directions. Bond fingers of each row are positioned between the overlapping surfaces of bond fingers of another row, which face each other, such that the bond fingers of the rows are arranged in a zigzag pattern.

### CROSS-REFERENCE TO RELATED APPLICATIONS

The present application claims priority to Korean patent application number 10-2006-0059812 filed on Jun. 29, 2006, which is incorporated by reference in its entirety.

### BACKGROUND OF THE INVENTION

The present invention relates to a semiconductor package, and more particularly, to a semiconductor package in which an interval between bond fingers connected to a semiconductor chip is increased while the size of a substrate is decreased.

In order to effect miniaturization, slimness and multiple functionalities of electronic appliances, new types of semiconductor packages, such as a chip scale package having a size corresponding to only 100% to 120% of the size of a semiconductor chip and a stack package having semiconductor chips stacked on one another, have been developed in the art.

As multiple functionalities are continuously demanded of electronic appliances and wherefore semiconductor chips are highly integrated, the number of bonding pads, which are formed on the surface of a semiconductor chip, significantly increases, and the number of bond fingers, which are formed on the surface of a substrate and electrically connected to the bonding pads, also increases. Therefore, the size of the substrate on which the semiconductor chip is mounted increases. Consequently, it is difficult to manufacture a chip scale package of a size that is only 100% to 120% of the size of a semiconductor chip, thereby retrogressing the trend of increasingly slimmer semiconductor packages.

Meanwhile, decreasing the interval between bond fingers in order to prevent the size of a semiconductor package from increasing results in wire bonding defects, arising from the process of connecting the bonding pads of a semiconductor chip to the bond fingers of a substrate using wires, and testing defects, arising from the process of testing the semiconductor package.

As a result, as the number of bonding pads arranged on the surface of a semiconductor chip continually increases, it becomes substantially impossible to design a substrate on which the semiconductor chip is mounted, whereby the semiconductor chip cannot be appropriately packaged.

### BRIEF SUMMARY OF THE INVENTION

Embodiments of the present invention are directed to a semiconductor package in which an interval between bond fingers is increased while the size of a substrate is decreased.

In one embodiment, a semiconductor package comprises a semiconductor chip having a plurality of bonding pads separately arranged on an upper surface thereof; a substrate to which the semiconductor chip is attached, the substrate having a first surface to which the semiconductor chip is attached and on which a plurality of bond fingers are arranged in a direction where the bonding pads of the semiconductor chip are arranged, and a second surface on which ball lands connected with the bond fingers are formed; wires for electrically connecting the bonding pads and the bond fingers to each other; a molding material for molding the first surface of the substrate, including the semiconductor chip, the bond fingers and the wires; and solder balls attached to the ball lands of the substrate, wherein the bond fingers are arranged in a plurality of rows and are formed in the shape of a polygon, such that overlapping surfaces of a bond finger of a row, which overlap with another bond finger of another row, have a constant slope, and overlapping surfaces of bond fingers arranged in the same row, which face each other, are sloped in opposite directions, and wherein bond fingers of each row are positioned between the overlapping surfaces of bond fingers of another row, which face each other, such that the bond fingers of the rows are arranged in a zigzag pattern.

The bond fingers are arranged in two rows.

The bond fingers have the shape of a diamond, a triangle, or a hexagon.

In the bond fingers arranged in two rows and having the shape of a diamond, a distance measured from the center of a bond finger arranged in the first row to the center of a bond finger arranged in the second row is greater than one-half of a length of the bond finger.

In the bond fingers arranged in two rows and having the shape of a triangle, the triangular shape of a bond finger arranged in the first row is symmetrical to the triangular shape of a bond finger arranged in the second row.

In another embodiment, a semiconductor package comprises a semiconductor chip having a plurality of bonding pads separately arranged on an upper surface thereof; conductive materials respectively formed on the bonding pads of the semiconductor chip; a substrate to which the semiconductor chip is attached by the medium of the conductive materials, the substrate having a first surface to which the semiconductor chip is attached and on which a plurality of bond fingers are arranged in a direction where the bonding pads of the semiconductor chip are arranged, and a second surface on which ball lands connected with the bond fingers are formed; a molding material for molding the semiconductor chip and the first surface of the substrate; and solder balls attached to the ball lands of the substrate, wherein the bond fingers are arranged in a plurality of rows, and are formed in the shape of a polygon, such that overlapping surfaces of a bond finger of a row, which overlap with another bond finger of another row, have a constant slope, and overlapping surfaces of bond fingers arranged in the same row, which face each other, are sloped in opposite directions, wherein bond fingers of each row are positioned between the overlapping surfaces of bond fingers of another row, which face each other, so that the bond fingers of the rows are arranged in a zigzag pattern, and wherein the bonding pads have the same shape and arrangement as the bond fingers.

The bond fingers are arranged in two rows.

The bond fingers have the shape of a diamond, a triangle, or a hexagon.

### BRIEF DESCRIPTION OF THE DRAWINGS

FIG. 1 is a plan view of a semiconductor package in accordance with a first embodiment of the present invention.

FIG. 2 is a cross-sectional view of the semiconductor package shown in FIG. 1.

FIG. 3A is a plan view illustrating bond fingers in accordance with the first embodiment of the present invention.

FIG. 3B is an enlarged view of part B of FIG. 3A.

FIGS. 4 and 5 are views illustrating variations of the bond fingers shown in FIG. 3.

FIG. 6A is a cross-sectional view illustrating a semiconductor package in accordance with a second embodiment of the present invention.

FIG. 6B is a plan view illustrating the semiconductor chip of the semiconductor package in accordance with the second embodiment of the present invention.

FIG. 6C is a plan view illustrating the substrate of the semiconductor package in accordance with the second embodiment of the present invention.

### DESCRIPTION OF SPECIFIC EMBODIMENTS

In the present invention, the shape of the bond finger of a substrate, which is connected to the bonding pad of a semiconductor chip using a wire or a bump, is changed from the conventional square or oblong shape to a diamond shape, and the bond fingers are arranged in two or more rows. Due to these facts, an increased number of bond fingers can be located on a substrate of limited size, and the interval between the bond fingers can be increased, thereby allowing a semiconductor package to satisfy the demand for multiple functionalities of electronic appliances.

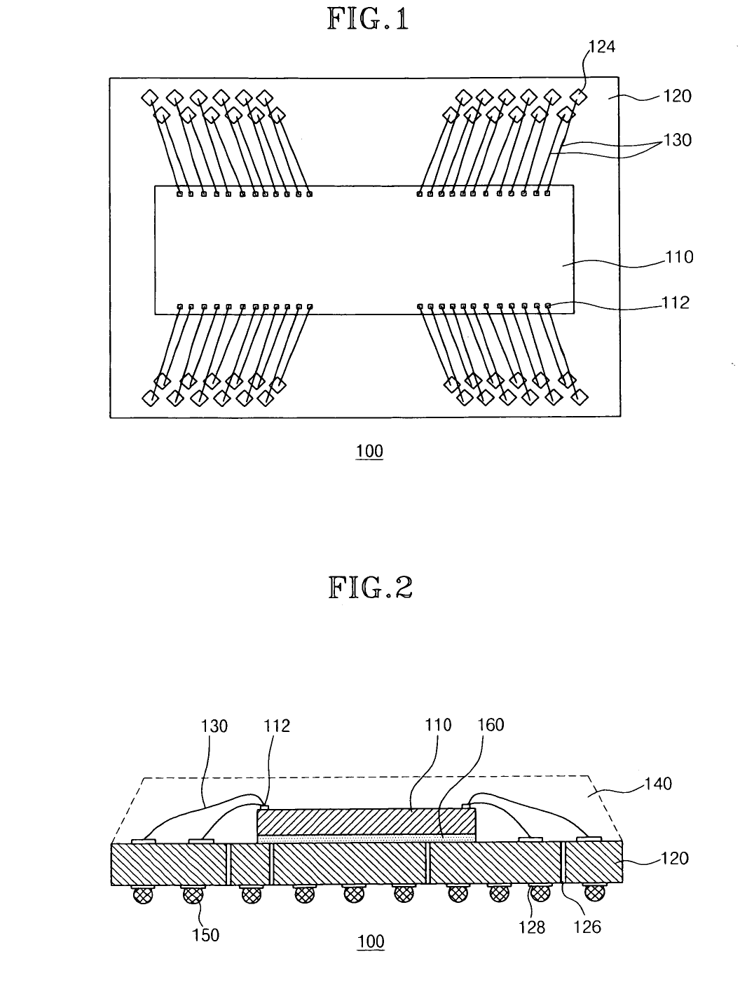

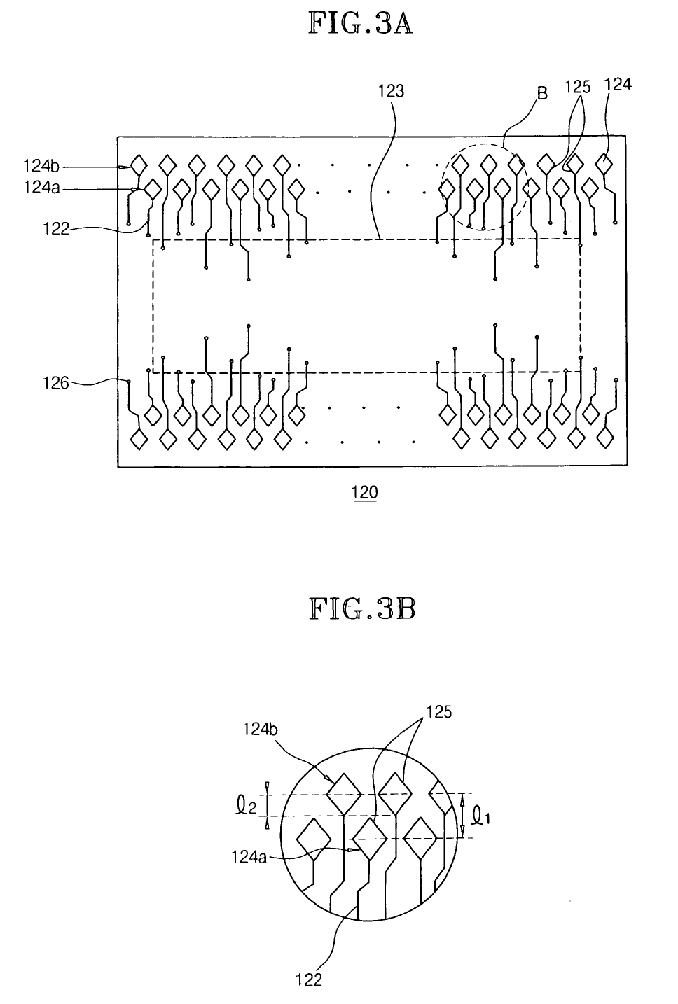

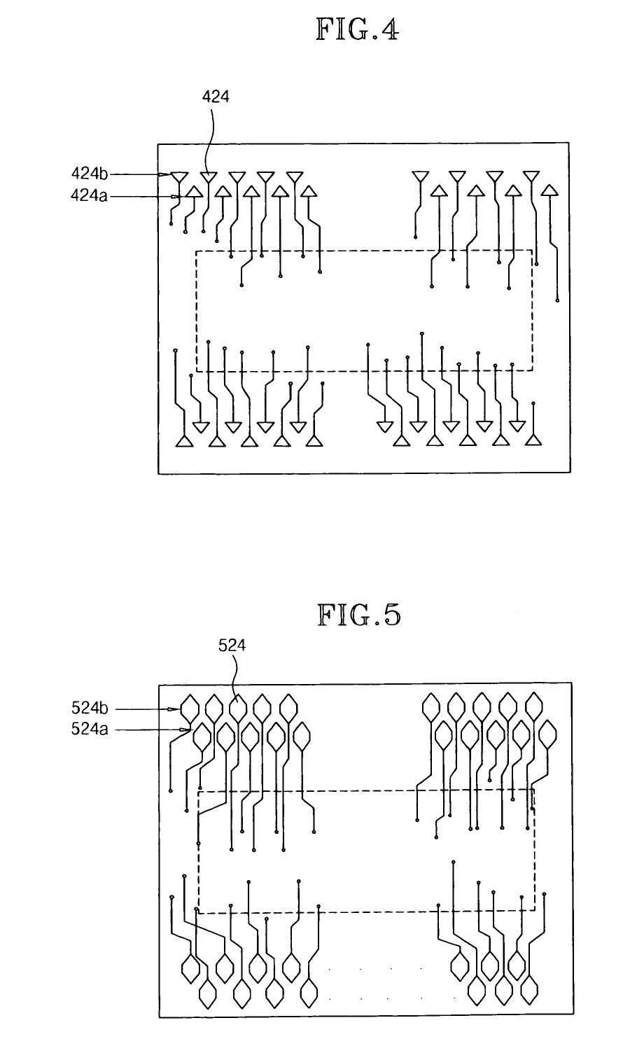

FIG. 1 is a plan view of a semiconductor package in accordance with the first embodiment of the present invention, FIG. 2 is a cross-sectional view of the semiconductor package shown in FIG. 1, FIG. 3A is a plan view illustrating bond fingers in accordance with the first embodiment of the present invention, and FIG. 3B is an enlarged view of part B of FIG. 3A.

Referring to FIGS. 1 and 2, a semiconductor package 100 in accordance with the first embodiment of the present invention includes a semiconductor chip 110, a substrate 120, wires 130, a molding material 140, and solder balls 150.

The semiconductor chip 110 has a circuit section (not shown) for storing various information inputted from the outside and a plurality of bonding pads 112, which are arranged on the upper surface of the semiconductor chip 110 and are electrically connected to the circuit section. In FIGS. 1 and 2, the bonding pads 112 are arranged in a row adjacent to each widthwise edge of the semiconductor chip 110. However, it is to be readily understood that the bonding pads 112 can be arranged in a row or a plurality of rows along the widthwise center portion of the semiconductor chip 110 or adjacent to the four edges of the semiconductor chip 110.

Referring to FIGS. 1 and 3A, the substrate 120 comprises a printed circuit board on which circuit patterns 122 are printed. The semiconductor chip 110 is attached to the substrate 120. The substrate 120 functions to electrically connect the semiconductor chip 110 and an electronic appliance to each other. A chip-attachment region 123 is defined on the center portion of the first surface, the upper surface of the substrate 120, and bond fingers 124 are arranged on the widthwise-peripheral portions of the upper surface of the substrate 120.

The semiconductor chip 110 is attached in the chip-attachment region 123 to the upper surface of the substrate 120. At this time, the semiconductor chip 110 is attached to the substrate 120 by means of an adhesive material 160 (see FIG. 2) on the lower surface thereof.

The bond fingers 124 are arranged in a plurality of rows, preferably two rows. If the bond fingers 124 are arranged in three or more rows, the size of the substrate 120 excessively increases due to the presence of the bond fingers 124, and it is difficult to miniaturize the semiconductor package 100. In consideration of this, the bond fingers 124 in the present embodiment are arranged in two rows such that the interval between the bond fingers 124 can be increased and the size of the substrate 120 can be decreased.

Referring to FIGS. 3A and 3B, the bond finger 124 is formed in the shape of a polygon having a plurality of surfaces and vertexes, the surfaces including overlapping surfaces 125 which overlap with the bond fingers 124 of the adjoining row. The overlapping surfaces 125 have a constant slope. The overlapping surfaces 125 of the bond fingers 124 arranged in the same row, which face each other, are sloped in opposite directions. Accordingly, as the overlapping surfaces 125 of the bond fingers 124b of the second row are positioned between the overlapping surfaces 125 of the bond fingers 124a of the first row, which face each other, the bond fingers 124a of the first row and the bond fingers 124b of the second row are arranged in a zigzag pattern.

Preferably, the respective bond fingers 124 arranged in the first and second rows are formed in the shape of a diamond. As the bond fingers 124 are formed in the shape of a diamond, an increased number of bond fingers 124 can be formed on the substrate 120 of predefined size. Therefore, even when the number of the bonding pads 112 of the semiconductor chip 110 to be attached to the substrate 120 is remarkably greater than that of a conventional semiconductor chip, the required number of bond fingers 124 can be entirely formed on the upper surface of the substrate 120 without increasing the size of the substrate 120. Further, when the number of the bonding pads 112 of the semiconductor chip 110 to be attached to the substrate 120 equals that of the bonding pads of a conventional semiconductor chip, the size of the substrate 120 can be decreased or the interval between the bond fingers 124 can be increased.

When the bond fingers 124 are formed in the shape of a diamond, as can be readily seen from FIG. 3B, the distance 11 measured from the center of the bond finger 124a arranged in the first row to the center of the bond finger 124b arranged in the second row must be greater than one-half of the length 12 of the bond finger 124 having the shape of a diamond.

FIGS. 4 and 5 are views illustrating bond fingers 424 and 524 having shapes that are different from the shape of the bond fingers 124 shown in FIG. 3.

While it is most preferred that the bond fingers 124 be formed in the shape of a diamond, as shown in FIG. 3A, it can be envisaged that bond fingers 424 are formed in the shape of a triangle, as shown in FIG. 4, or bond fingers 524 can be formed in the shape of a hexagon, as shown in FIG. 5.

In the case where the bond fingers 424 are formed in the shape of a triangle, as shown in FIG. 4, the triangular shape of the bond fingers 424a arranged in the first row is symmetrical to the triangular shape of the bond fingers 424b arranged in the second row. In FIG. 5, the reference numeral 524a designates the bond fingers arranged in the first row, and the reference numeral 524b designates the bond fingers arranged in the second row.

Referring again to FIGS. 1 and 2, ball lands 128, that are connected to the bond fingers 124 by the circuit patterns 122 and via holes 126, are formed on the lower surface of the substrate 120. The solder balls 150, which serve as input and output terminals of the semiconductor package 100, are respectively attached to the ball lands 128.

The wires 130 are made of a conductive material and serve to electrically connect the bonding pads 112 of the semiconductor chip 110 and the bond fingers 124 of the substrate 120 to each other. One end of the wire 130 is connected to the bonding pad 112 of the semiconductor chip 110, and the other end of the wire 130 is connected to the bond finger 124 of the substrate 120.

After the semiconductor chip 110 and the substrate 120 are electrically connected to each other by the wires 130, the upper surface of the substrate 120, including the semiconductor chip 110, the bond fingers 124 of the substrate 120 and the wires 130, is molded using the molding material 140, as shown by dotted lines in FIG. 2, thereby ensuring its protection from outer circumstances. For example, the molding material 140 comprises an epoxy molding compound.

In the present embodiment, when the bond fingers 124 are formed in the shape of a polygon, such as a diamond, and are arranged zigzag in two or more rows, the size of the semiconductor package 100 can be decreased, and the semiconductor package 100 of a semiconductor chip 110 having a large number of bonding pads 112 can be miniaturized.

Also, since the interval between the bond fingers 124 can be increased, the operational reliability of the semiconductor package 100 can be improved.

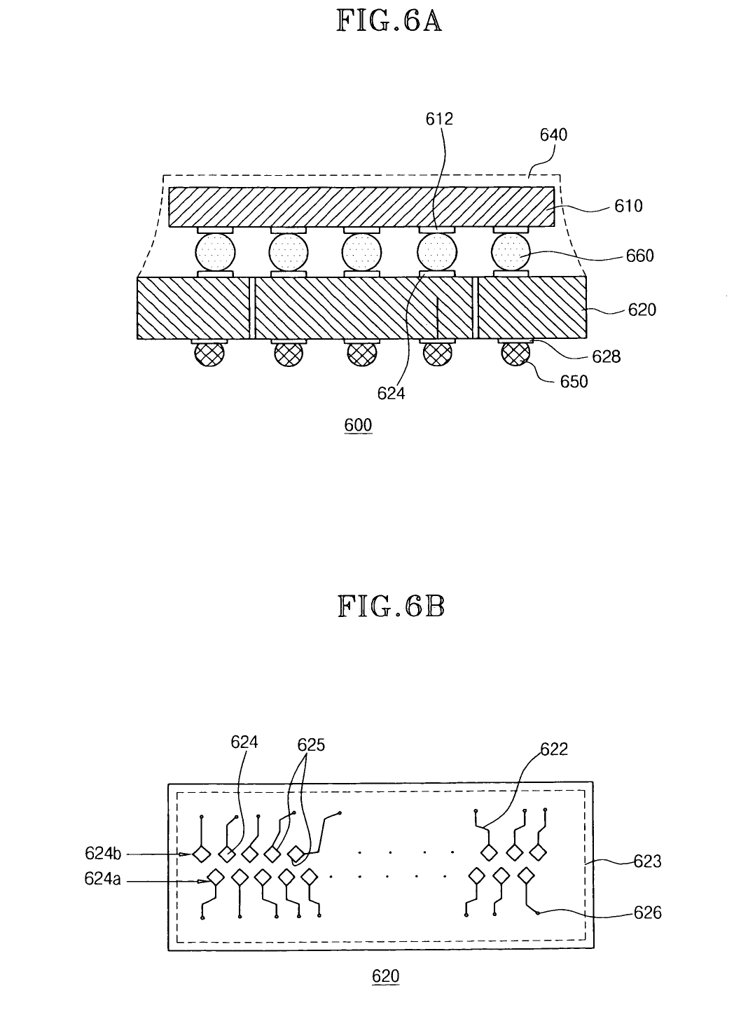

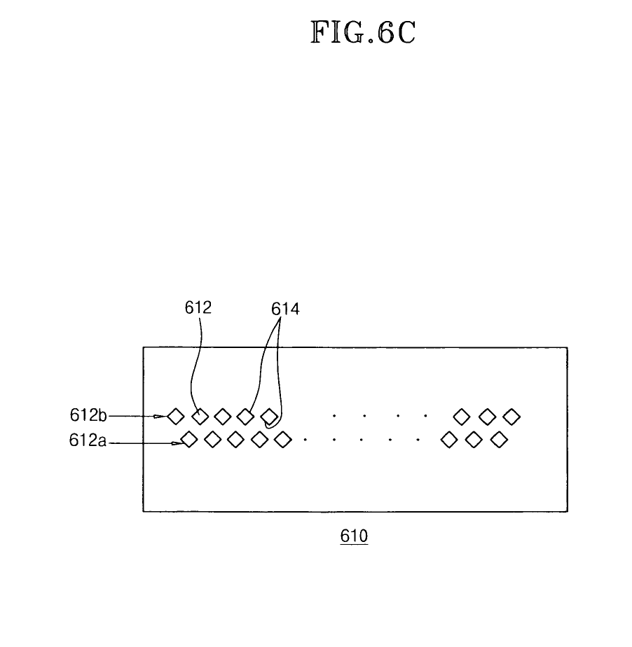

FIGS. 6A through 6C are views for explaining a semiconductor package in accordance with the second embodiment of the present invention, wherein FIG. 6A is a cross-sectional view illustrating the semiconductor package, FIG. 6B is a plan view illustrating the semiconductor chip of the semiconductor package, and FIG. 6C is a plan view illustrating the substrate of the semiconductor package.

Referring to FIG. 6A, the semiconductor package 600 in accordance with the second embodiment of the present invention has a configuration in which a semiconductor chip 610 and a substrate 620 are connected to each other not by wires but by conductive materials, namely solder bumps 660. In other words, in the semiconductor package 600 in accordance with this second embodiment of the present invention, after the solder bumps 660 are respectively formed on the bonding pads 612 of the semiconductor chip 610, the semiconductor chip 610 is attached to the substrate 620 using the solder bumps 660, such that the electrical connections between the bonding pads 612 of the semiconductor chip 610 and the bond fingers 624 of the substrate 620 are formed by the solder bumps 660. The upper surfaces of the semiconductor chip 610 and the substrate 620 are molded by a molding material 640, thereby ensuring their protection from the outer circumstances. Solder balls 650 are attached to the ball lands 628 of the substrate 620.

The bond fingers 624 having the same shape and arrangement as described in the first embodiment are formed on the upper surface of the substrate 620. The bonding pads 612 having the same shape and arrangement as the bond fingers 624 are formed on the lower surface of the semiconductor chip 610.

Specifically, referring to FIG. 6B, the bond fingers 624 are formed on the substrate in a plurality of rows, for example, two rows. Each bond finger 624 is formed in the shape of a polygon having a plurality of surfaces and vertexes, the surfaces including overlapping surfaces 625 that overlap with the bond fingers 624 of the adjoining row. For example, the bond finger 624 can be formed in the shape of a diamond, a triangle, or a hexagon. Preferably, the bond finger 624 is formed in the shape of a diamond. As the overlapping surfaces 625 of the bond fingers 624b of the second row are positioned between the overlapping surfaces 625 of the bond fingers 624a of the first row, which face each other, the bond fingers 624a of the first row and the bond fingers 624b of the second row are arranged in a zigzag pattern.

Referring to FIG. 6C, the bonding pads 612 are formed on the lower surface of the semiconductor chip 610 in a plurality of rows, for example, two rows. Each bonding pad 612 is formed in the shape of a polygon having a plurality of surfaces and vertexes, the surfaces including overlapping surfaces 614 which overlap with the bonding pads 612 of the adjoining row. For example, the bonding pad 612 is formed in the shape of a diamond. As the overlapping surfaces 614 of the bonding pads 612b of the second row are positioned between the overlapping surfaces 614 of the bonding pads 612a of the first row, which face each other, the bonding pads 612a of the first row and the bonding pads 612b of the second row are arranged in a zigzag pattern. In FIG. 6B, the reference numeral 622 designates circuit patterns, 623 a chip attachment region, and 626 via holes.

In the semiconductor package 600 in accordance with the second embodiment of the present invention, since the interval between the bond fingers 624 can be increased, the reliability of the electrical connections can be improved when the semiconductor chip 610 and the substrate 620 are electrically connected using the solder bumps 660.

As is apparent from the above description, the semiconductor package according to the present invention provides advantages in that, since bond fingers are formed to have the shape of a polygon such as a diamond and are arranged zigzag in a plurality of rows, a semiconductor chip having a number of bonding pads can be packaged, and the size of a substrate can be decreased, thereby allowing the semiconductor package to be miniaturized. Further, because the interval between the bond fingers can be increased, the operational reliability of the semiconductor package can be improved.

Although a preferred embodiment of the present invention has been described for illustrative purposes, those skilled in the art will appreciate that various modifications, additions and substitutions are possible without departing from the scope and the spirit of the invention as disclosed in the accompanying claims.

What is claimed is:

1. A semiconductor package comprising:
a semiconductor chip having a plurality of bonding pads separately arranged on an upper surface thereof;
a substrate to which the semiconductor chip is attached, the substrate having a first surface to which the semiconductor chip is attached and on which a plurality of bond fingers are arranged in a direction where the bonding pads of the semiconductor chip are arranged, and a second surface on which ball lands connected to the bond fingers are formed;
wires for electrically connecting the bonding pads and the bond fingers to each other;
a molding material for molding the first surface of the substrate, including the semiconductor chip, the bond fingers and the wires; and
solder balls attached to the ball lands of the substrate,
wherein the bond fingers, each formed in a polygon shape having multiple sides, are arranged in a plurality of rows such that the slopes of two nearest sides of two bond fingers arranged in two adjacent rows are substantially same, and such that the slopes of two sides of two nearest bond fingers arranged in the same row are opposite to each other, and
wherein the bond fingers in a row are not arranged to substantially block a line of path between each bond finger in another row and a portion of the first area on the semiconductor substrate to which the semiconductor chip is attached such that the bond fingers of the two adjacent rows are arranged to resemble a zigzag pattern.

2. The semiconductor package of claim 1, wherein the bond fingers are arranged in two rows.

3. The semiconductor package of claim 2, wherein the bond fingers have the shape of a diamond.

4. The semiconductor package of claim 3, wherein, in the bond fingers having the shape of a diamond that are arranged in two rows being a first and second rows, a distance measured from a center of a bond finger arranged in the first row to a center of a bond finger arranged in the second row is greater than one-half of a length of the bond finger.

5. The semiconductor package of claim 2, wherein the bond fingers have the shape of a triangle.

6. The semiconductor package of claim 5, wherein, in the bond fingers having the shape of a triangle that are arranged in two rows being a first and second rows, the triangular shape of a bond finger arranged in the first row is symmetrical to the triangular shape of a bond finger arranged in the second row.

7. The semiconductor package of claim 2, wherein the bond fingers have the shape of a hexagon.

8. A semiconductor package comprising:
a semiconductor chip having a plurality of bonding pads separately arranged on an upper surface thereof;
a conductive material formed on each of the bonding pads of the semiconductor chip;
a substrate having a first surface to which the conductive materials connected to the semiconductor chip are attached and on which a plurality of bond fingers are arranged in a direction where the bonding pads of the semiconductor chip are arranged, and having a second surface on which ball lands connected to the bond fingers are formed;
a molding material for molding at least the semiconductor chip on the first surface of the substrate; and
solder balls attached to the ball lands of the substrate,
wherein the bond fingers, each formed in a polygon shape having multiple sides, are arranged in a plurality of rows such that the slopes of two nearest sides of two bond fingers arranged in two adjacent rows are substantially same, and such that the slopes of two sides of two nearest bond fingers arranged in the same row are opposite to each other,
wherein the bond fingers in each row are arranged such that the bond fingers of the two adjacent rows are arranged to resemble a zigzag pattern, and
wherein the bonding pads have the same shape and arrangement as the bond fingers.

9. The semiconductor package of claim 8, wherein the bond fingers are arranged in two rows.

10. The semiconductor package of claim 9, wherein the bond fingers have the shape of a diamond.

11. The semiconductor package of claim 9, wherein the bond fingers have the shape of a triangle.

12. The semiconductor package of claim 9, wherein the bond fingers have the shape of a hexagon.
